(19) United States
(12) Patent Application Publication
(10) Pub. No.: US 2013/0191048 A1
(43) Pub. Date: Jul. 25, 2013

(54) METHOD AND DEVICE FOR ESTIMATING DAMAGE TO A MAGNETIC TUNNEL JUNCTION (MTJ) ELEMENT

(71) Applicants: Xia Li, San Diego, CA (US); Wei-Chuan Chen, Taipei (TW); Seung H. Kang, San Diego, CA (US)

(72) Inventors: Xia Li, San Diego, CA (US); Wei-Chuan Chen, Taipei (TW); Seung H. Kang, San Diego, CA (US)

(73) Assignee: QUALCOMM Incorporated, San Diego, CA (US)

(21) Appl. No.: 13/357,417

(22) Filed: Jan. 24, 2012

(51) Int. Cl. G01R 31/26; G06F 19/00

(52) U.S. Cl. 702/58; 324/762.01

(57) ABSTRACT

A method of estimating damage to a magnetic tunnel junction (MTJ) element that includes providing an MTJ element having a magnetic barrier layer, the magnetic barrier layer having a periphery, a cross-sectional area and a thickness and comprising an inner region of undamaged magnetic barrier material and an outer region of damaged magnetic barrier material between the inner region and the periphery, determining a first value indicative of an electrical characteristic of the MTJ element, determining a second value indicative of the electrical characteristic that the MTJ element would have had if the outer region of damaged magnetic barrier material were not present and if the inner region of undamaged magnetic barrier material extended to the periphery, and calculating a value indicative of the size of the outer region of damaged magnetic barrier material from the first value and the second value. Also a computer configured to perform the method.

### FIELD OF THE DISCLOSURE

The present application for patent is directed toward a method for estimating an amount of damage to the magnetic barrier layer and/or free layer of a magnetic tunnel junction (MTJ) element and toward a device for performing such estimation, and, more specifically, toward a method of estimating an amount of damage to the magnetic barrier layer and/or free layer of an MTJ element based on a value of an electrical characteristic of the MTJ element and a value that the electrical characteristic would have had if its magnetic barrier layer and/or free layer were not damaged and toward a device for performing such estimation.

### BACKGROUND

Magnetic tunnel junction (MTJ) elements comprise first and second magnetic elements separated by a layer of magnetic barrier material. The magnetic orientation of the first magnetic element is fixed, and the magnetic orientation of the second magnetic element can be changed by applying a magnetic field or current to the MTJ element, depending on the type of MTJ used. The MTJ element has a first resistance when the magnetic orientations of the first and second magnetic elements are the same or parallel and a second, different, resistance when the magnetic orientations of the first and second magnetic elements are opposite or antiparallel. These two states can be used to represent a digital “0” and “1,” and the MTJ element can thus be used as a memory element in which the measured resistance indicates the magnetic orientation of the second magnetic element and thus the value stored by the element.

During manufacturing and/or processing, the sidewall of an MTJ element may become chemically or physically damaged. For example, when processing is carried out using certain etchants and encapsulants, oxygen and/or other elements can diffuse into the periphery of the magnetic barrier layer and free layer and chemically damage the layers, or the magnetic barrier layer and free layer may be physically damaged by processing. This results in a ring-shaped outer region of the magnetic barrier layer that has a higher resistance than that of the undamaged magnetic barrier layer material in the center of the magnetic barrier layer which in turn affects the resistance of the MTJ element and reduces effective working MTJ area. Such damage may make it more difficult to determine whether a given measurement of the MTJ elements indicates that the MTJ element is in a parallel or antiparallel state for small MTJ size. This problem becomes more pronounced as the size of an MTJ element decreases. It would therefore be desirable to estimate the amount of damage to the magnetic barrier layer and free layer of an MTJ element so that manufacturing processes can be tuned to minimize and/or better control this damage.

### SUMMARY

An exemplary embodiment includes a method of estimating damage to a magnetic tunnel junction (MTJ) element that includes providing an MTJ element having a magnetic barrier layer, the magnetic barrier layer having a periphery, a cross-sectional area and a thickness and comprising an inner region of undamaged magnetic barrier material and an outer region of damaged magnetic barrier material between the inner region and the periphery. The method also includes determining a first value indicative of an electrical characteristic of the MTJ element, determining a second value indicative of the electrical characteristic that the MTJ element would have had if the outer region of damaged magnetic barrier material were not present and if the inner region of undamaged magnetic barrier material extended to the periphery, and calculating a value indicative of the size of the outer region of damaged magnetic barrier material from the first value and the second value.

Another exemplary embodiment includes a computer configured to determine, for an MTJ element comprising a magnetic barrier layer having a periphery, a cross-sectional area and a thickness, the magnetic barrier layer comprising an inner region of undamaged magnetic barrier material and an outer region of damaged magnetic barrier material between the inner region and the periphery, a size of the outer region. The computer includes a memory storing a first value indicative of an electrical characteristic of the MTJ element and a second value indicative of the electrical characteristic that the MTJ element would have had if the outer region of damaged magnetic barrier material were not present and if the inner region of undamaged magnetic barrier material extended to the periphery and logic configured to calculate the size of the outer region from the first value and the second value.

A further embodiment comprises a method of estimating damage to an MTJ element comprising steps for providing an MTJ element having a magnetic barrier layer, the magnetic barrier layer having a periphery, a cross-sectional area and a thickness and comprising an inner region of undamaged magnetic barrier material and an outer region of damaged magnetic barrier material between the inner region and the periphery. The method also includes steps for determining a first value indicative of an electrical characteristic of the MTJ element, steps for determining a second value indicative of the electrical characteristic that the MTJ element would have had if the outer region of damaged magnetic barrier material were not present and if the inner region of undamaged magnetic barrier material extended to the periphery, and steps for calculating a value indicative of the size of the outer region of damaged magnetic barrier material from the first value and the second value.

A further embodiment comprises a computer configured to determine, for an MTJ element comprising a magnetic barrier layer having a periphery, a cross-sectional area and a thickness, the magnetic barrier layer comprising an inner region of undamaged magnetic barrier material and an outer region of damaged magnetic barrier material between the inner region and the periphery, a size of the outer region. The computer includes memory means for storing a first value indicative of an electrical characteristic of the MTJ element and a second value indicative of the electrical characteristic that the MTJ element would have had if the outer region of damaged magnetic barrier material were not present and if the inner region of undamaged magnetic barrier material extended to the periphery and logic means for calculating the size of the outer region from the first value and the second value.

Another embodiment includes a non-transitory computer-readable medium comprising instructions which, when executed by a computer cause the computer to perform operations for characterizing an MTJ element having a magnetic barrier layer. The magnetic barrier layer has a periphery, a cross-sectional area and a thickness and comprises an inner region of undamaged magnetic barrier material and an outer region of damaged magnetic barrier material between the inner region and the periphery. The instructions include instructions for determining a first value indicative of an electrical characteristic of the MTJ element, instructions for determining a second value indicative of the electrical characteristic that the MTJ element would have had if the outer region of damaged magnetic barrier material were not present and if the inner region of undamaged magnetic barrier material extended to the periphery and instructions for calculating a value indicative of the size of the outer region of damaged magnetic barrier material from the first value and the second value.

Yet another embodiment comprises a method of estimating sidewall damage to an electrical element that has a periphery, a cross-sectional area and a thickness and an inner region of undamaged material and an outer region of damaged material between the inner region and the periphery. The method includes determining a first value indicative of an electrical characteristic of the element, determining a second value indicative of the electrical characteristic that the element would have had if the outer region of damaged material were not present and if the inner region of undamaged material extended to the periphery, and calculating a value indicative of the size of the outer region of damaged material from the first value and the second value.

### BRIEF DESCRIPTION OF THE DRAWINGS

The accompanying drawings are presented to aid in the description of embodiments of the invention and are provided solely for illustration of the embodiments and not limitation thereof.

FIG. 1 is a schematic elevational view of an MTJ element having a magnetic barrier layer.

FIG. 2 is a sectional plan view taken in the direction of line I-I of FIG. 1 showing damaged and undamaged portions of the magnetic barrier layer of the MTJ element of FIG. 1.

FIG. 3 is a perspective view of a piece of undamaged magnetic barrier material.

FIG. 4 is a perspective view of a computer configured to determine a size of a damaged region of a magnetic barrier layer of an MTJ element.

FIG. 5 is a flowchart illustrating a method according to an embodiment.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

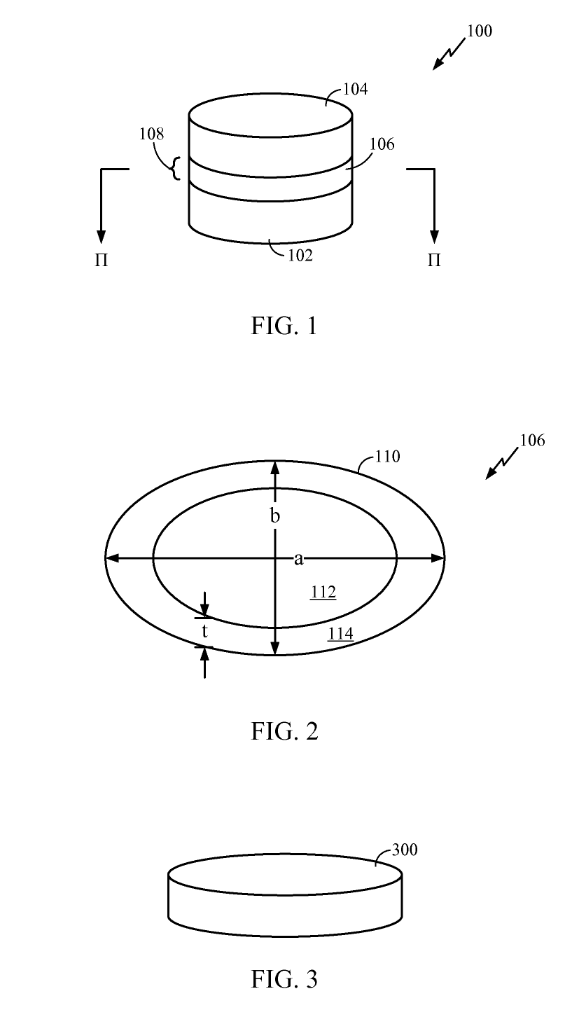

FIG. 1 illustrates an MTJ element 100 that includes a first, fixed, magnetic layer 102, a second, free, magnetic layer 104 and a magnetic barrier layer 106 having a thickness 108. (The fixed magnetic layer 102 and the free magnetic layer 104 can be switched in FIG. 1.) An anti-ferromagnetic layer (not illustrated) may be located under the fixed magnetic layer 102 to pin the fixed magnetic layer 102. FIG. 2 is a plan view of the magnetic barrier layer 106 showing the periphery 110 of the magnetic barrier layer 106, an inner region 112 of undamaged magnetic barrier material and an outer region 114 of damaged magnetic barrier material. The magnetic barrier layer 106 has a first dimension a, representing the major axis of the elliptical MTJ element 100, and a second dimension b, representing the minor axis of the elliptical MTJ element 100, which first and second dimensions would be equal in the case of an MTJ element having a circular cross section. The cross sectional area A of the MTJ element 100 is

$$A = \frac{π}{4} a \cdot b .$$

The depth of the outer region 114 from the periphery 110 to the inner region 112 is represented by the letter t. The foregoing discussion also applies to circular MTJ elements, which are treated as a special case of an elliptical MTJ element for which a=b.

In a first embodiment, the depth t of the outer region 114 can be estimated from physical properties of the MTJ element 100, such as the area of the inner region 112 and the area of the outer region 114, the electrical characteristics of the MTJ element 100 such as its resistance and switching current, based on a current flow therethrough, for example, and knowledge of the electrical characteristics that would be possessed by an MTJ element having a magnetic barrier layer comprised solely of an undamaged region 112 that extends to the periphery 110 of the magnetic barrier layer 106. The properties of such an undamaged MTJ element can be determined theoretically based on knowledge of the properties of the magnetic barrier material forming the magnetic barrier layer 106 or empirically by measuring properties of a piece of magnetic barrier material 300, illustrated in FIG. 3, that has a cross sectional area equal to the cross sectional area of the magnetic barrier layer 106 and a thickness equal to the thickness of the magnetic barrier layer 106.

In the following discussion, “R” refers to resistance and “A” refers to area. The subscript “1” indicates that a given variable relates to a feature of the inner region 112 of the magnetic barrier layer 106, the subscript “2” indicates that a given variable relates to the outer region 114. Rp refers to the parallel state resistance of the MTJ element 100, and variables without a subscript relate to the piece of magnetic barrier material 300 or a theoretical, undamaged piece of undamaged magnetic barrier material having the dimensions and shape of the magnetic barrier layer 106.

It is known that

$${R}_{1} = \frac{{R}_{1} {A}_{1}}{{A}_{1}} = \frac{RA}{{A}_{1}} = \frac{1}{{cA}_{1}} ∝ \frac{1}{{A}_{1}} , where c = \frac{1}{RA}$$

and that

$${R}_{2} = \frac{{R}_{2} {A}_{2}}{{A}_{2}} = \frac{1}{{dA}_{2}} ∝ \frac{1}{{A}_{2}} , where d = \frac{1}{{R}_{2} {A}_{2}} .$$

In addition, the area A of the magnetic barrier layer 106 is equal to the sum of the area A1 of the inner region 112 and the area A2 of the outer region 114, or A=A₁+A₂ and that the area of this elliptical magnetic barrier layer 106 is

$$A = \frac{π}{4} a \cdot b .$$

The major axis a of the outer region 114 is greater than the major axis of the inner region 112 by an amount equal to 2t, the minor axis b of the outer region 114 is greater than the minor axis of the inner region by an amount equal to 2t, and the area of the inner region 112 can therefore be expressed as

$${A}_{1} = \frac{π}{4} ( a - 2 t ) \cdot ( b - 2 t ) .$$

The resistance of the magnetic barrier layer 106 is equal to the resistance of the inner region 112 taken in parallel with the resistance of the outer region 114 and thus

$$\frac{1}{{R}_{p}} = \frac{1}{{R}_{1}} + \frac{1}{{R}_{2}} = {cA}_{1} + {dA}_{2} = ( c - d ) {A}_{1} + dA .$$

From this it follows that

$$( \frac{1}{{R}_{p} A} - \frac{1}{RA} ) ( \frac{ab}{a + b} ) = ( ( \frac{1}{RA} - d ) 2 {t}^{2} ) ( \frac{2}{a - b} ) - ( \frac{1}{RA} - d ) 2 t . \qquad ( Equation 1 a )$$

For a given MTJ element 100, Rp can be measured directly, and the areas and dimensions of the inner region 112 plus the outer region 114 and the magnetic barrier layer 106 can be measured directly. In addition, the RA value can be measured from a blank MTJ test wafer by current in-plane tunneling (CIPT). Those known values can be substituted for the values in Equation 1a, and Equation 1a can then be solved for t. These estimated values for t can be compared as process parameters are changed and to help refine a manufacturing process and obtain an acceptable value of t. A perpendicular MTJ with circular shape can use same equation by setting a equal to b.

A similar analysis can be applied to MTJ switching current with the same result based on the following analysis.

$$\begin{matrix}{I}_{c} = {I}_{c 1} + {I}_{c 2} \\ = {J}_{c 1} \cdot {A}_{1} + {J}_{c 2} \cdot {A}_{2} \\ = {J}_{c 1} \cdot \frac{π}{4} ( a - 2 t ) ( b - 2 t ) + {J}_{c 2} \cdot \\ [ \frac{π}{4} ab - \frac{π}{4} ( a - 2 t ) ( b - 2 t ) ] \\ = {J}_{c 1} \cdot \frac{π}{4} ab [ ( 1 - \frac{2 t}{a} ) ( 1 - \frac{2 t}{b} ) + \frac{{J}_{c 2}}{{J}_{c 1}} ( 2 t ( \frac{1}{a} + \frac{1}{b} ) - \frac{4 {t}^{2}}{ab} ) ] \\ \approx {J}_{c 1} \cdot \frac{π}{4} ab ( 1 - \frac{2 t}{a} ) ( 1 - \frac{2 t}{b} ) ( if {J}_{c 1} >> {J}_{c 2} ) \\ \approx {J}_{c 0} [ 1 - [ \frac{{k}_{B} \cdot T}{{E}_{B}} ] ln ( {τ}_{0} \cdot {t}_{p} ) ] \cdot \frac{π}{4} ab ( 1 - \frac{2 t}{a} ) ( 1 - \frac{2 t}{b} )\end{matrix}$$

In addition,

$${E}_{B} = \frac{{M}_{s} \cdot {K}_{k} \cdot V}{2} = \frac{{M}_{s} \cdot {K}_{k} \cdot A \cdot {t}_{f}}{2} ∝ {( {M}_{s} \cdot {t}_{f} )}^{2} \cdot {A}_{1}$$

$$and$$

$$\frac{{E}_{B}}{{k}_{B} T} >> \vert ln ( {τ}_{0} \cdot {t}_{p} ) \vert$$

wherein EB is MTJ barrier, Ms is saturation magnetization, and Kk is the isotropic field. Furthermore A is MTJ area, tf is MTJ free layer thickness, τ0 is MTJ intrinsic switching time, and tp is MTJ switching pulse. In addition,

$${I}_{c} \approx {J}_{c 0} \cdot \frac{π}{4} ab ( 1 - \frac{2 t}{a} ) ( 1 - \frac{2 t}{b} ) ( \frac{{E}_{B}}{{k}_{B} \cdot T} \sim 60 >> \vert ln ( {τ}_{0} \cdot {t}_{p} ) \vert ) \approx {J}_{c 0} \cdot \frac{π}{4} ab [ 1 - 2 t ( \frac{1}{a} + \frac{1}{b} ) + \frac{4 {t}^{2}}{ab} ] \approx {J}_{c 0} \cdot \frac{π}{4} ab [ 1 - 2 t ( \frac{1}{a} + \frac{1}{b} ) ] ( if t << \frac{\sqrt{ab}}{2} , \frac{a + b}{2} ) \approx - {J}_{c 0} \cdot A \cdot t ( \frac{2}{a} + \frac{2}{b} ) + {J}_{c 0} \cdot A \qquad ( Equation 1 b )$$

where Jc0 is the intrinsic MTJ switching current density and EB is the switching barrier. From Ic and MTJ CD data, we can also extract MTJ sidewall damage from equation 1b.

In another embodiment, certain assumptions can be made to simply calculations and to allow the calculations to be based on a smaller number of measurements. This embodiment is useful when t is small and the outer region 114 has a very high resistance. “Small” means that

$$t << \frac{\sqrt{a \cdot b}}{2}$$

and “very high resistance” means that R₂A₂>>RA. In this case Equation 1 can be simplified as

$$\begin{matrix}\frac{1}{{R}_{p} A} ≅ - \frac{t}{RA} ( \frac{2}{a} + \frac{2}{b} ) + \frac{1}{RA} & ( Equation 2 ) \\ or \frac{1}{{R}_{p}} ≅ - \frac{t}{{R}_{0}} ( \frac{2}{a} + \frac{2}{b} ) + \frac{1}{{R}_{0}} & ( Equation 3 a )\end{matrix}$$

where R0 is the resistance of the piece 300 of undamaged magnetic barrier material. From applying small constant voltage for test, equation 3a can be derived as

$${I}_{c} ≅ - t \cdot {I}_{c 0} ( \frac{2}{a} + \frac{2}{b} ) + {I}_{c 0} . \qquad ( Equation 3 b )$$

In these equations, Ic is the MTJ switching current as in equation 1b. This allows estimates of t to be derived without determining the areas of the inner region 112 or the outer region 114 and testing blank MTJ wafer RA value by CIPT.

In another embodiment, the resistance of the outer region 114 is treated as being constant and not dependent on area. In this case,

$$\frac{1}{{R}_{p}} = \frac{1}{{R}_{1}} + \frac{1}{{R}_{2}} = {cA}_{1} + d = {cA}_{1} + d \qquad$$

from which it follows that

$$( \frac{1}{{R}_{p}} - \frac{A}{RA} ) = - \frac{π}{RA} t ( \frac{a + b}{2} ) + ( \frac{π}{RA} {t}^{2} + \frac{1}{{R}_{2}} ) . \qquad ( Equation 4 )$$

Under a final set of assumptions, the resistance R2 of the outer region 114 is assumed to be infinite and thus to have no affect on the foregoing calculations. In that case,

$$( \frac{π}{4} ab - \frac{RA}{{R}_{p}} ) = ( A - {A}_{1} ) = π t ( \frac{a + b}{2} ) - π {t}^{2} and , \\ if ( \frac{a + b}{2} ) >> t , then \\ \frac{1}{{R}_{p} A} \approx \frac{1}{RA} [ - t ( \frac{2}{a} + \frac{2}{b} ) + 1 ] \approx - \frac{t}{RA} \cdot ( \frac{2}{a} + \frac{2}{b} ) + \frac{1}{RA} \qquad ( Equation 5 )$$

when resistance is measured and

$${J}_{c} \approx {J}_{c 0} [ - t ( \frac{2}{a} + \frac{2}{b} ) + 1 ] \approx - {J}_{c 0} \cdot t ( \frac{2}{a} + \frac{2}{b} ) + {J}_{c 0} \qquad ( Equation 6 )$$

when switching current is measured.

This is similar to equation 2 and implies equations 3a and 3b. This provides yet another method of estimating t and the amount of damage to the sidewall of the MTJ element 100 and its magnetic barrier layer 106. Considering MTJ parallel and anti-parallel switching current may be different, Equations 1b, 3b, and 6 can be used for both switching current or current density.

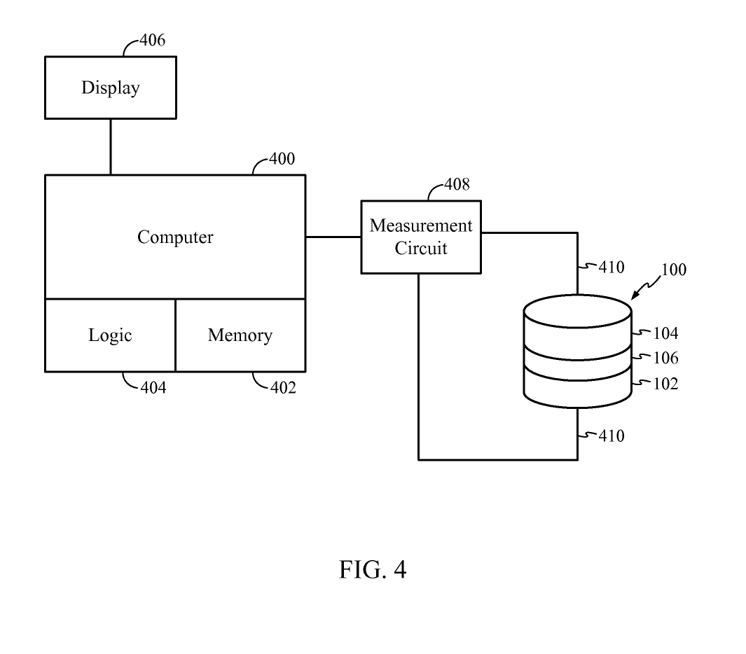

FIG. 4 illustrates a computer 400 configured to estimate the sidewall damage size t of the outer region 114 based on various inputs which computer 400 includes a memory 402 and logic 404 configured to determine t from the inputs discussed in the various methods described above. The computer 400 may include a display 406 for displaying a numerical value indicative of a value of t, or the display 406 may output a graph (not illustrated) of various relations among the aforementioned variables to allow the effect of changes in size of the outer region 114 to be visualized. A measurement circuit 408 or other measurement tool, including appropriate probes or connectors 410 is connected to the computer 400 for measuring the electrical characteristic of the MTJ element 100, and, optionally, for measuring the electrical characteristic of the piece of undamaged magnetic barrier material 300 by CIPT using a similar system.

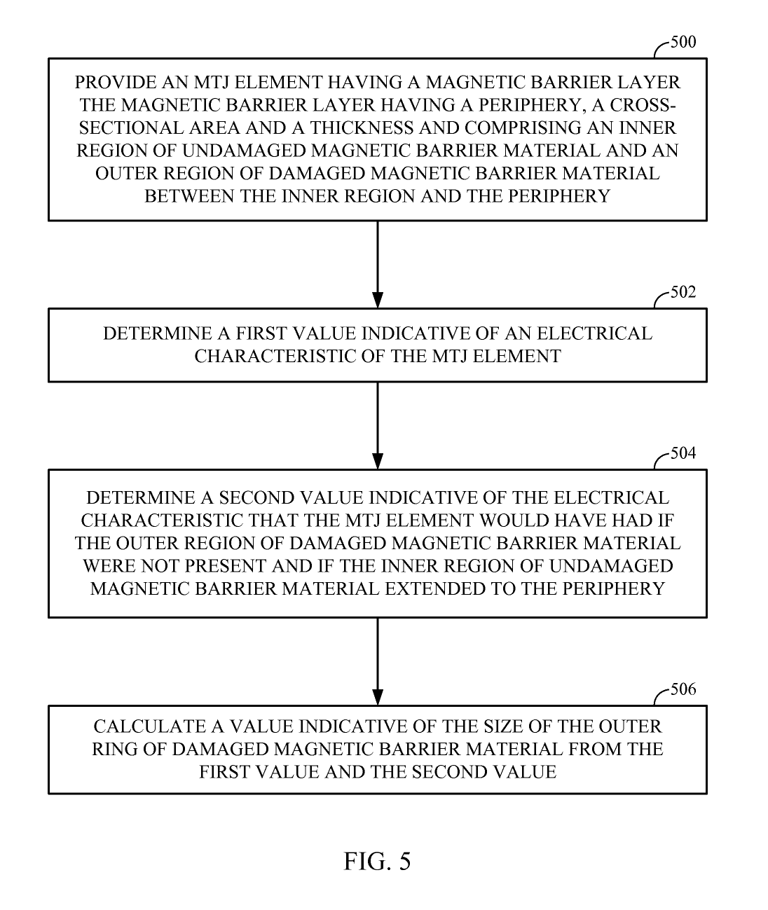

FIG. 5 illustrates a method according to an embodiment that includes a block 500 of providing an MTJ element having a magnetic barrier layer, the magnetic barrier layer having a periphery, a cross-sectional area and a dimension and comprising an inner region of undamaged magnetic barrier material and an outer region of damaged magnetic barrier material between the inner region and the periphery, a block 502 of determining a first value indicative of an electrical characteristic of the MTJ element, a block 504 of determining a second value indicative of the electrical characteristic that the MTJ element would have had if the outer region of damaged magnetic barrier material were not present and if the inner region of undamaged magnetic barrier material extended to the periphery, and a block 506 of calculating a value indicative of the size of the outer ring of damaged magnetic barrier material from the first value and the second value.

In fact, according to above method and analysis, a more general solution can be obtained for extracting pattern sidewall damage impact that is not limited to MTJ's. In such case, the pattern shape can be a circle, an oval, a square or any other regular shape. In this case, If P∝A(x,y) then pattern sidewall damage correlates as

$$P ≅ - t \cdot {P}_{0} ( \frac{2}{x} + \frac{2}{y} ) + {P}_{0} if t << \frac{x + y}{2} and \frac{\sqrt{x \cdot y}}{2}$$

where P is an electrical or other test parameter from the pattern, x and y are pattern dimension, P0 is an ideal parameter of the pattern without sidewall damage and

$$( \frac{2}{x} + \frac{2}{y} )$$

is a common edge impact factor.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for determining damage to an MTJ element having a magnetic barrier layer, the magnetic barrier layer having a periphery, a cross-sectional area and a thickness and comprising an inner region of undamaged magnetic barrier material and an outer region of damaged magnetic barrier material between the inner region and the periphery, the method including obtaining a first value indicative of an electrical characteristic of the MTJ element, obtaining a second value indicative of the electrical characteristic that the MTJ element would have had if the outer region of damaged magnetic barrier material were not present and if the inner region of undamaged magnetic barrier material extended to the periphery and calculating a value indicative of the size of the outer ring of damaged magnetic barrier material from the first value and the second value.

Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method of estimating damage to a magnetic tunnel junction (MTJ) element comprising:
providing an MTJ element having a magnetic barrier layer, the magnetic barrier layer having a periphery, a cross-sectional area and a thickness and comprising an inner region of undamaged magnetic barrier material and an outer region of damaged magnetic barrier material between the inner region and the periphery;
determining a first value indicative of an electrical characteristic of the MTJ element;
determining a second value indicative of the electrical characteristic that the MTJ element would have had if the outer region of damaged magnetic barrier material were not present and if the inner region of undamaged magnetic barrier material extended to the periphery; and
calculating a value indicative of the size of the outer region of damaged magnetic barrier material from the first value and the second value.

2. The method of claim 1, wherein the electrical characteristic is resistance or current or current density.

3. The method of claim 1, wherein determining a first value comprises connecting the MTJ element to a measurement circuit or measurement tool configured to measure the first value and measuring the first value using the measurement circuit or measurement tool.

4. The method of claim 1, wherein determining a second value comprises connecting a piece of undamaged magnetic barrier material to a measurement circuit or measurement tool and using the measurement circuit or measurement tool to measure the electrical characteristic of the piece of undamaged magnetic barrier material.

5. The method of claim 1, wherein calculating the value indicative of the size of the outer region comprises calculating a width t of the outer region between the periphery and the inner region.

6. The method of claim 5, wherein t is determined from a relationship:
$$( \frac{1}{{R}_{p} A} - \frac{1}{RA} ) ( \frac{ab}{a + b} ) = ( ( \frac{1}{RA} - d ) 2 {t}^{2} ) ( \frac{2}{a + b} ) - ( \frac{1}{RA} - d ) 2 t$$
when the electrical characteristic is resistance or
$$( {J}_{c} - {J}_{cb} ) ( \frac{ab}{a + b} ) = ( ( {J}_{cb} - {d}^{′} ) 2 {t}^{2} ) ( \frac{2}{a + b} ) - ( {J}_{cb} - {d}^{′} ) 2 t$$
when the electrical characteristic is current density or
$$( {I}_{c} - {I}_{cb} ) ( \frac{ab}{a + b} ) = ( ( {I}_{cb} - {d}^{″} ) 2 {t}^{2} ) ( \frac{2}{a + b} ) - ( {I}_{cb} - {d}^{″} ) 2 t$$
when the electrical characteristic is current,
where Rp, J_{c}, or I_{c}=the first value,
A=the cross-sectional area of the magnetic barrier layer,
RA, J_{cb}, or I_{cb}=the second value,
a=a first dimension of the MTJ element,
b=a second dimension of the MTJ element measured perpendicularly to the first dimension, and
d, d′, or d″=an inverse of a product of an area and a resistance of the outer region.

7. The method of claim 5, wherein t is determined from a relationship:
$$\frac{1}{{R}_{p} } ≅ - \frac{t}{R} ( \frac{2}{a} + \frac{2}{b} ) + \frac{1}{R}$$
when the electrical characteristic is resistance or
$${I}_{c} ≅ - t \cdot {I}_{c 0} ( \frac{2}{a} + \frac{2}{b} ) + {I}_{c 0}$$
when the electrical characteristic is current,
where
Rp, or I_{c}=the first value,
R, or I_{c0}=second value,
a=a first dimension of the MTJ, and
b=a second dimension of the MTJ measured perpendicularly to the first dimension.

8. The method of claim 5, wherein the electrical characteristic is resistance and wherein t is determined from a relationship:
$$( \frac{1}{{R}_{p}} - \frac{A}{RA} ) = - \frac{π}{RA} t ( \frac{a + b}{2} ) + ( \frac{π}{RA} {t}^{2} + \frac{1}{{R}_{2}} )$$
where
Rp=the first value,
A=the cross-sectional area of the magnetic barrier layer,
RA=second value,
a=a first dimension of the MTJ, and
b=a second dimension of the MTJ measured perpendicularly to the first dimension.

9. The method of claim 5, wherein t is determined from a relationship:
$$\frac{1}{{R}_{p} A} \approx - \frac{t}{RA} \cdot ( \frac{2}{a} + \frac{2}{b} ) + \frac{1}{RA}$$
when the electrical characteristic is resistance or
$${J}_{c} \approx - {J}_{c 0} \cdot t ( \frac{2}{a} + \frac{2}{b} ) + {J}_{c 0}$$
when the electrical characteristic is current density, and
where Rp, or J_{c}=the first value,
A=the cross-sectional area of the magnetic barrier layer,
RA, or J_{c0}=the second value,
a=a first dimension of the MTJ, and
b=a second dimension of the MTJ measured perpendicular to the first dimension.

10. The method of claim 5, wherein P is a test parameter, P₀ is an ideal value of the test parameter without sidewall damage and wherein t is determined from the relationship:
$$P ≅ - t \cdot {P}_{0} ( \frac{2}{x} + \frac{2}{y} ) + {P}_{0} if t << \frac{x + y}{2} and \frac{\sqrt{x \cdot y}}{2}$$
where x and y are MTJ dimensions.

11. A computer configured to determine, for a magnetic tunnel junction (MTJ) element comprising a magnetic barrier layer having a periphery, a cross-sectional area and a thickness, the magnetic barrier layer comprising an inner region of undamaged magnetic barrier material and an outer region of damaged magnetic barrier material between the inner region and the periphery, a size of the outer region, the computer comprising:
a memory storing a first value indicative of an electrical characteristic of the MTJ element and a second value indicative of the electrical characteristic that the MTJ element would have had if the outer region of damaged magnetic barrier material were not present and if the inner region of undamaged magnetic barrier material extended to the periphery; and
logic configured to calculate the size of the outer region from the first value and the second value.

12. The computer of claim 11, wherein the electrical characteristic comprises resistance or current or current density.

13. The computer of claim 11, wherein the logic is configured to calculate a width t of the outer region between the periphery and the inner region.

14. The computer of claim 11, including a measurement circuit configured to measure the electrical characteristic of the MTJ element and to provide a value indicative of the electrical characteristic of the MTJ element to the memory.

15. The computer of claim 13, wherein the logic is configured to calculate the width t based on a formula:
$$( \frac{1}{{R}_{p} A} - \frac{1}{RA} ) ( \frac{ab}{a + b} ) = ( ( \frac{1}{RA} - d ) 2 {t}^{2} ) ( \frac{2}{a + b} ) - ( \frac{1}{RA} - d ) 2 t$$
when the electrical characteristic is resistance or
$$( {J}_{c} - {J}_{cb} ) ( \frac{ab}{a + b} ) = ( ( {J}_{cb} - {d}^{′} ) 2 {t}^{2} ) ( \frac{2}{a + b} ) - ( {J}_{cb} - {d}^{′} ) 2 t$$
when the electrical characteristic is current density or
$$( {I}_{c} - {I}_{cb} ) ( \frac{ab}{a + b} ) = ( ( {I}_{cb} - {d}^{″} ) 2 {t}^{2} ) ( \frac{2}{a + b} ) - ( {I}_{cb} - {d}^{″} ) 2 t$$
when the electrical characteristic is current, and
where Rp, J_{c}, or I_{c}=the first value,
A=the cross-sectional area of the magnetic barrier layer,
RA, J_{cb}, or I_{cb}=the second value,
a=a first dimension of the MTJ element,
b=a second dimension of the MTJ element measured perpendicularly to the first dimension, and
d, d′, or d″=an inverse of a product of an area and a resistance of the outer region.

16. The computer of claim 13, wherein the logic is configured to calculate the width t based on a formula:
$$\frac{1}{{R}_{p}} \approx - \frac{t}{R} ( \frac{2}{a} + \frac{2}{b} ) + \frac{1}{R}$$
when the electrical characteristic is resistance or
$${I}_{c} ≅ - t \cdot {I}_{c 0} ( \frac{2}{a} + \frac{2}{b} ) + {I}_{c 0}$$
when the electrical characteristic is current, and
where
Rp, or I_{c}=the first value,
R, or I_{c0}=second value,
a=a first dimension of the MTJ, and
b=a second dimension of the MTJ measured perpendicularly to the first dimension.

17. The computer of claim 13, wherein the logic is configured to calculate the width t based on a formula:
$$( \frac{1}{{R}_{p}} - \frac{A}{RA} ) = - \frac{π}{RA} t ( \frac{a + b}{2} ) + ( \frac{π}{RA} {t}^{2} + \frac{1}{{R}_{2}} )$$
where
Rp=the first value,
A=the cross-sectional area of the magnetic barrier layer,
R=second value,
a=a first dimension of the MTJ, and
b=a second dimension of the MTJ measured perpendicularly to the first dimension.

18. The computer of claim 13, wherein the logic is configured to calculate the width t based on a formula:
$$\frac{1}{{R}_{p} A} \approx - \frac{t}{RA} \cdot ( \frac{2}{a} + \frac{2}{b} ) + \frac{1}{RA}$$
when the electrical characteristic is resistance or
$${J}_{c} \approx - {J}_{c 0} \cdot t ( \frac{2}{a} + \frac{2}{b} ) + {J}_{c 0}$$
when the electrical characteristic is current density, and
where Rp, or J_{c}=the first value,
A=the cross-sectional area of the MTJ,
RA, or J_{c0}=the second value,
a=a first dimension of the MTJ, and
b=a second dimension of the MTJ measured perpendicular to the first dimension.

19. The computer of claim 13, wherein the logic is configured to calculate the width t based on a formula:
$$P ≅ - t \cdot {P}_{0} ( \frac{2}{x} + \frac{2}{y} ) + {P}_{0} if t ≪ \frac{x + y}{2} and \frac{\sqrt{x \cdot y}}{2}$$
wherein P is a test parameter, P₀ is an ideal value of the test parameter without sidewall damage and wherein x and y are MTJ dimensions.

20. A method of estimating damage to a magnetic tunnel junction (MTJ) element comprising:
steps for providing an MTJ element having a magnetic barrier layer, the magnetic barrier layer having a periphery, a cross-sectional area and a thickness and comprising an inner region of undamaged magnetic barrier material and an outer region of damaged magnetic barrier material between the inner region and the periphery;
steps for determining a first value indicative of an electrical characteristic of the MTJ element;
steps for determining a second value indicative of the electrical characteristic that the MTJ element would have had if the outer region of damaged magnetic barrier material were not present and if the inner region of undamaged magnetic barrier material extended to the periphery; and
steps for calculating a value indicative of the size of the outer region of damaged magnetic barrier material from the first value and the second value.

21. The method of claim 20, wherein the electrical characteristic is resistance or current or current density.

22. The method of claim 20, wherein the steps for determining a first value comprise steps for connecting the MTJ element to a measurement circuit or measurement tool configured to measure the first value and steps for measuring the first value using the measurement circuit or measurement tool.

23. The method of claim 20, wherein the steps for determining a second value comprise connecting a piece of undamaged magnetic barrier material to a measurement circuit or measurement tool and steps for using the measurement circuit or measurement tool to measure the electrical characteristic of the piece of undamaged magnetic barrier material.

24. The method of claim 20, wherein the steps for calculating the value indicative of the size of the outer region comprise calculating a width t of the outer region between the periphery and the inner region.

25. The method of claim 24, wherein t is determined from a relationship:
$$( \frac{1}{{R}_{p} A} - \frac{1}{RA} ) ( \frac{ab}{a + b} ) = ( ( \frac{1}{RA} - d ) 2 {t}^{2} ) ( \frac{2}{a + b} ) - ( \frac{1}{RA} - d ) 2 t$$
when the electrical characteristic is resistance, or
$$( {J}_{c} - {J}_{cb} ) ( \frac{ab}{a + b} ) = ( ( {J}_{cb} - {d}^{′} ) 2 {t}^{2} ) ( \frac{2}{a + b} ) - ( {J}_{cb} - {d}^{′} ) 2 t$$
when the electrical characteristic is current density, or
$$( {I}_{c} - {I}_{cb} ) ( \frac{ab}{a + b} ) = ( ( {I}_{cb} - {d}^{″} ) 2 {t}^{2} ) ( \frac{2}{a + b} ) - ( {I}_{cb} - {d}^{″} ) 2 t$$
when the electrical characteristic is current, and
where Rp, J_{c}, or I_{c}=the first value,
A=the cross-sectional area of the magnetic barrier layer,
RA, J_{cb}, or I_{cb}=the second value,
a=a first dimension of the MTJ element,
b=a second dimension of the MTJ element measured perpendicularly to the first dimension, and
d, d′, or d″=an inverse of a product of an area and a resistance of the outer region.

26. The method of claim 24, wherein t is determined from a relationship:
$$\frac{1}{{R}_{p}} ≅ - \frac{t}{R} ( \frac{2}{a} + \frac{2}{b} ) + \frac{1}{R}$$
when the electrical characteristic is resistance or
$${I}_{c} ≅ - t \cdot {I}_{c 0} ( \frac{2}{a} + \frac{2}{b} ) + {I}_{c 0}$$
when the electrical characteristic is current, and
where
Rp, or I_{c}=the first value,
R, or I_{c0}=second value,
a=a first dimension of the MTJ, and
b=a second dimension of the MTJ measured perpendicularly to the first dimension.

27. The method of claim 24, wherein the electrical characteristic is resistance and wherein t is determined from a relationship:
$$( \frac{1}{{R}_{p}} - \frac{A}{RA} ) = - \frac{π}{RA} t ( \frac{a + b}{2} ) + ( \frac{π}{RA} {t}^{2} + \frac{1}{{R}_{2}} )$$
where
Rp=the first value,
A=the cross-sectional area of the magnetic barrier layer,
RA=second value,
a=a first dimension of the MTJ, and
b=a second dimension of the MTJ measured perpendicularly to the first dimension.

28. The method of claim 24, wherein t is determined from a relationship:
$$\frac{1}{{R}_{p} A} \approx - \frac{t}{RA} \cdot ( \frac{2}{a} + \frac{2}{b} ) + \frac{1}{RA}$$
when the electrical characteristic is resistance, or
$${J}_{c} \approx - {J}_{c 0} \cdot t ( \frac{2}{a} + \frac{2}{b} ) + {J}_{c 0}$$
when the electrical characteristic is current density, and
where Rp, or J_{c}=the first value,
A=the cross-sectional area of the magnetic barrier layer,
RA, or J_{c0}=the second value,
a=a first dimension of the MTJ, and
b=a second dimension of the MTJ measured perpendicular to the first dimension.

29. The method of claim 24, wherein P is a test parameter, P₀ is an ideal value of the test parameter without sidewall damage and wherein t is determined from the relationship:
$$P ≅ - t \cdot {P}_{0} ( \frac{2}{x} + \frac{2}{y} ) + {P}_{0} if t ≪ \frac{x + y}{2} and \frac{\sqrt{x \cdot y}}{2}$$
where x and y are MTJ dimensions.

30. A computer configured to determine, for a magnetic tunnel junction (MTJ) element comprising a magnetic barrier layer having a periphery, a cross-sectional area and a thickness, the magnetic barrier layer comprising an inner region of undamaged magnetic barrier material and an outer region of damaged magnetic barrier material between the inner region and the periphery, a size of the outer region, the computer comprising:
memory means for storing a first value indicative of an electrical characteristic of the MTJ element and a second value indicative of the electrical characteristic that the MTJ element would have had if the outer region of damaged magnetic barrier material were not present and if the inner region of undamaged magnetic barrier material extended to the periphery; and
logic means for calculating the size of the outer region from the first value and the second value.

31. The computer of claim 30, wherein the electrical characteristic comprises resistance or current or current density.

32. The computer of claim 30, wherein the logic means is for calculating a width t of the outer region between the periphery and the inner region.

33. The computer of claim 30, including measurement circuit means configured to measure the electrical characteristic of the MTJ element and to provide a value indicative of the electrical characteristic of the MTJ element to the memory.

34. The computer of claim 30, wherein the logic means is for calculating the width t based on a formula:
$$( \frac{1}{{R}_{p} A} - \frac{1}{RA} ) ( \frac{ab}{a + b} ) = ( ( \frac{1}{RA} - d ) 2 {t}^{2} ) ( \frac{2}{a + b} ) - ( \frac{1}{RA} - d ) 2 t$$
when the electrical characteristic is resistance, or
$$( {J}_{c} - {J}_{cb} ) ( \frac{ab}{a + b} ) = ( ( {J}_{cb} - {d}^{′} ) 2 {t}^{2} ) ( \frac{2}{a + b} ) - ( {J}_{cb} - {d}^{′} ) 2 t$$
when the electrical characteristic is current density, or
$$( {I}_{c} - {I}_{cb} ) ( \frac{ab}{a + b} ) = ( ( {I}_{cb} - {d}^{″} ) 2 {t}^{2} ) ( \frac{2}{a + b} ) - ( {I}_{cb} - {d}^{″} ) 2 t$$
when the electrical characteristic is current, and
where Rp, J_{c}, or I_{c}=the first value,
A=the cross-sectional area of the magnetic barrier layer,
RA, J_{cb}, or I_{cb}=the second value,
a=a first dimension of the MTJ element,
b=a second dimension of the MTJ element measured perpendicularly to the first dimension, and
d, d′, or d″=an inverse of a product of an area and a resistance of the outer region.

35. The computer of claim 32, wherein the logic means is for calculating the width t based on a formula:
$$\frac{1}{{R}_{p}} ≅ - \frac{t}{R} ( \frac{2}{a} + \frac{2}{b} ) + \frac{1}{R}$$
when the electrical characteristic is resistance, or
$${I}_{c} ≅ - t \cdot {I}_{c 0} ( \frac{2}{a} + \frac{2}{b} ) + {I}_{c 0}$$
when the electrical characteristic is current, and
where
Rp, or I_{c}=the first value,
R, or I_{c0}=second value,
a=a first dimension of the MTJ, and
b=a second dimension of the MTJ measured perpendicularly to the first dimension.

36. The computer of claim 32, wherein the logic means is for calculating the width t based on a formula:
$$( \frac{1}{{R}_{p}} - \frac{A}{RA} ) = - \frac{π}{RA} t ( \frac{a + b}{2} ) + ( \frac{π}{RA} {t}^{2} + \frac{1}{{R}_{2}} )$$
where
Rp=the first value,
A=the cross-sectional area of the magnetic barrier layer,
R=second value,
a=a first dimension of the MTJ, and
b=a second dimension of the MTJ measured perpendicularly to the first dimension.

37. The computer of claim 32, wherein the logic means is for calculating the width t based on a formula:
$$\frac{1}{{R}_{p} A} \approx - \frac{t}{RA} \cdot ( \frac{2}{a} + \frac{2}{b} ) + \frac{1}{RA}$$
when the electrical characteristic is resistance or
$${J}_{c} \approx - {J}_{c 0} \cdot t ( \frac{2}{a} + \frac{2}{b} ) + {J}_{c 0}$$
when the electrical characteristic is current density, and
where Rp, or J_{c}=the first value,
A=the cross-sectional area of the MTJ,
RA, or J_{c0}=the second value,
a=a first dimension of the MTJ, and
b=a second dimension of the MTJ measured perpendicular to the first dimension.

38. The computer of claim 32, wherein the logic is configured to calculate the width t based on a formula:
$$P ≅ - t \cdot {P}_{0} ( \frac{2}{x} + \frac{2}{y} ) + {P}_{0} if t ≪ \frac{x + y}{2} and \frac{\sqrt{x \cdot y}}{2}$$
wherein P is a test parameter, P₀ is an ideal value of the test parameter without sidewall damage and wherein x and y are MTJ dimensions.

39. A non-transitory computer-readable medium comprising instructions which, when executed by a computer cause the computer to perform operations for characterizing an MTJ element having a magnetic barrier layer, the magnetic barrier layer having a periphery, a cross-sectional area and a thickness and comprising an inner region of undamaged magnetic barrier material and an outer region of damaged magnetic barrier material between the inner region and the periphery, the instructions including instructions for determining a first value indicative of an electrical characteristic of the MTJ element, instructions for determining a second value indicative of the electrical characteristic that the MTJ element would have had if the outer region of damaged magnetic barrier material were not present and if the inner region of undamaged magnetic barrier material extended to the periphery and instructions for calculating a value indicative of the size of the outer region of damaged magnetic barrier material from the first value and the second value.

40. The computer-readable medium of claim 39, wherein the instructions for calculating the value indicative of the size of the outer region comprises instructions for calculating a width t of the outer region between the periphery and the inner region.

41. The computer-readable medium of claim 40, wherein the electrical characteristic is resistance and wherein the instructions for calculating t comprise instructions for calculating t based on the relationship:
$$( \frac{1}{{R}_{p} A} - \frac{1}{RA} ) ( \frac{ab}{a + b} ) = ( ( \frac{1}{RA} - d ) 2 {t}^{2} ) ( \frac{2}{a + b} ) - ( \frac{1}{RA} - d ) 2 t$$
when the electrical characteristic is resistance, or
$$( {J}_{c} - {J}_{cb} ) ( \frac{ab}{a + b} ) = ( ( {J}_{cb} - {d}^{′} ) 2 {t}^{2} ) ( \frac{2}{a + b} ) - ( {J}_{cb} - {d}^{′} ) 2 t$$
when the electrical characteristic is current density, or
$$( {I}_{c} - {I}_{cb} ) ( \frac{ab}{a + b} ) = ( ( {I}_{cb} - {d}^{″} ) 2 {t}^{2} ) ( \frac{2}{a + b} ) - ( {I}_{cb} - {d}^{″} ) 2 t$$
when the electrical characteristic is current, and
where Rp, J_{c}, or I_{c}=the first value,
A=the cross-sectional area of the magnetic barrier layer,
RA, J_{cb}, or I_{cb}=the second value,
a=a first dimension of the MTJ element,
b=a second dimension of the MTJ element measured perpendicularly to the first dimension, and
d, d′, or d″=an inverse of a product of an area and a resistance of the outer region.

42. The computer-readable medium of claim 40, wherein the instructions for calculating t comprise instructions for calculating t based on the relationship:
$$\frac{1}{{R}_{p}} ≅ - \frac{t}{R} ( \frac{2}{a} + \frac{2}{b} ) + \frac{1}{R}$$
when the electrical characteristic is resistance, or
$${I}_{c} ≅ - t \cdot {I}_{c 0} ( \frac{2}{a} + \frac{2}{b} ) + {I}_{c 0}$$
when the electrical characteristic is current, and
where
Rp, or I_{c}=the first value,
R, or I_{c0}=second value,
a=a first dimension of the MTJ, and
b=a second dimension of the MTJ measured perpendicularly to the first dimension.

43. The computer-readable medium of claim 40, wherein the electrical characteristic is resistance and wherein the instructions for calculating t comprise instructions for calculating t based on the relationship:
$$( \frac{1}{{R}_{p}} - \frac{A}{RA} ) = - \frac{π}{RA} t ( \frac{a + b}{2} ) + ( \frac{π}{RA} {t}^{2} + \frac{1}{{R}_{2}} )$$
where
Rp=the first value,
A=the cross-sectional area of the magnetic barrier layer,
RA=second value,
a=a first dimension of the MTJ, and
b=a second dimension of the MTJ measured perpendicularly to the first dimension.

44. The computer-readable medium of claim 40, wherein the instructions for calculating t comprise instructions for calculating t based on the relationship:
$$\frac{1}{{R}_{p} A} \approx - \frac{t}{RA} \cdot ( \frac{2}{a} + \frac{2}{b} ) + \frac{1}{RA}$$
when the electrical characteristic is resistance, or
$${J}_{c} \approx - {J}_{c 0} \cdot t ( \frac{2}{a} + \frac{2}{b} ) + {J}_{c 0}$$
when the electrical characteristic is current density, and
where Rp, or J_{c}=the first value,
A=the cross-sectional area of the magnetic barrier layer,
RA, or J_{c0}=the second value,
a=a first dimension of the MTJ, and
b=a second dimension of the MTJ measured perpendicular to the first dimension.

45. The computer-readable medium of claim 40, wherein P is a test parameter, P₀ is an ideal value of the test parameter without sidewall damage and wherein t is determined from the relationship:
$$P ≅ - t \cdot {P}_{0} ( \frac{2}{x} + \frac{2}{y} ) + {P}_{0} if t ≪ \frac{x + y}{2} and \frac{\sqrt{x \cdot y}}{2}$$
where x and y are MTJ dimensions.

46. A method of estimating sidewall damage to an electrical element comprising:
providing an electrical element having a periphery, a cross-sectional area and a thickness and comprising an inner region of undamaged material and an outer region of damaged material between the inner region and the periphery;
determining a first value indicative of an electrical characteristic of the element;
determining a second value indicative of the electrical characteristic that the element would have had if the outer region of damaged material were not present and if the inner region of undamaged material extended to the periphery; and
calculating a value indicative of the size of the outer region of damaged material from the first value and the second value.

47. The method of claim 46, wherein calculating the value indicative of the size of the outer region comprises calculating a width t of the outer region between the periphery and the inner region, wherein P is an electrical test parameter, P₀ is an ideal value of the electrical test parameter without sidewall damage and wherein t is determined from the relationship:
$$P ≅ - t \cdot {P}_{0} ( \frac{2}{x} + \frac{2}{y} ) + {P}_{0} if t ≪ \frac{x + y}{2} and \frac{\sqrt{x \cdot y}}{2}$$
where x and y are dimensions of the electrical element.
